(19) United States
(12) Patent Application Publication
(10) Pub. No.: US 2023/0049235 A1
(43) Pub. Date: Feb. 16, 2023

(54) COMPLEX OXIDE MEMRISTIVE MATERIAL, MEMRISTOR COMPRISING SUCH MATERIAL, AND FABRICATION THEREOF

(71) Applicant: Turun Yliopisto, Turun Yliopisto (FI)

(72) Inventors: Petriina PATURI, Turun yliopisto (FI); Alejandro SCHULMAN, Turun yliopisto (FI); Hannu HUHTINEN, Turun yliopisto (FI); Ville LÄHTEENLAHTI, Turun yliopisto (FI); Azar BEIRANVAND, Turun yliopisto (FI)

(21) Appl. No.: 17/796,819

(22) PCT Filed: Jan. 29, 2021
(86) PCT No.: PCT/FI2021/050057

§ 371 Date: Aug. 1, 2022

(30) Foreign Application Priority Data
Jan. 31, 2020 (FI) 20205101

(51) Int. Cl. H01L 45/00; C01G 45/12

(52) U.S. Cl. CPC H01L 45/147; H01L 45/08; H01L 45/1226; H01L 45/1253; H01L 45/1625; C01G 45/1207; C01P 2002/50; C01P 2006/40

(57) ABSTRACT

A memristor material is disclosed which has the chemical formula R₁₋ₓAₓB0₃, wherein R is one of Eu, Gd, Tb, Nd, A is one of Ca, Sr, Ba, B is one of Mn, Co, Ni, and x is larger than 0 but smaller than 1, a preferred example being Gd₁₋ₓCaₓMn0₃ (GCMO) with x not less than 0.2 to obtain practical resistance switching ratios. A memristor can be manufactured by pulsed laser deposition using a sintered target of said material.

### FIELD OF THE INVENTION

The invention concerns memristors, i.e. electronic components the current-conducting properties of which depend on electric conditions they have been previously subjected to. In particular the invention concerns a memristor that comprises a complex oxide as the memristive material, said complex oxide comprising gadolinium, calcium and manganese.

### BACKGROUND OF THE INVENTION

Memristors are electronic components the current-conducting properties of which depend on electric conditions they have been previously subjected to. As an example, FIG. 1 illustrates a memristor 101, the resistance of which is marked with R. Instead of resistance one could consider its inverse value, i.e. conductance. A voltage across the memristor 101 is U, and a current through the memristor 101 is I. The memristor 101 may exhibit a so-called high resistivity state HRS or a so-called low resistivity state LRS, somewhat idealized illustrations of which are shown in the current per voltage diagram of FIG. 2. The HRS appears as a horizontal line 201 along or very close to the x-axis, meaning that only a very small current flows through the memristor irrespective of the voltage. The LRS state appears as a diagonal line 202, meaning that the current I through the memristor 101 is a linear function of the voltage according to I=U/R.

The memristor 101 of FIGS. 1 and 2 exhibits bipolar switching between the HRS and the LRS. This means that switching from HRS to LRS takes place at a different polarity of the voltage U than switching from LRS to HRS. In FIG. 2, if the memristor is initially in the HRS and the positive voltage across it reaches a first threshold point 203, the memristor switches into the LRS according to arrow 204. If the operation in the negative end of the LRS region reaches a second threshold point 205, the memristor switches back into the HRS according to arrow 206.

A memristor becomes highly interesting for a number of possible applications if the switching between HRS and LRS remains fully reversible even after a large number of cycles, and even more importantly if it can be made to obey a linear relationship between the voltage (or other quantity) used to make the HRS→LRS transition and the resistance R thus obtained. The latter property would mean a kind of analog control of conductance, and it would have interesting applications in neuromorphic computing, in which the conductances of memristors could be used to represent the weights or strengths of synaptic connections between nodes in the neural network. With memristors of prior art it has proven to be difficult to obtain the sufficient linearity. For the purpose of use in micro-electronic circuits it should be possible to manufacture the memristor in a thin film form.

### SUMMARY

There is therefore an objective to present a thin film material for memristor, and a memristor comprising such material, with which the dependence between the quantity used to establish the LRS conductivity and the conductivity value thus obtained can be made linear.

The objective is achieved by using a low bandwidth perovskite of formula R₍₁₋ₓ₎AₓBO₃ as the memristor material, where R is one of Eu, Gd, Tb, Nd; A is one of Ca, Sr, Ba; B is one of Mn, Co, Ni; and x is larger than 0 but smaller than 1.

According to a first aspect there is provided a material for memristor, said material having the chemical formula R₍₁₋ₓ₎AₓBO₃, where R is one of Eu, Gd, Tb, Nd; A is one of Ca, Sr, Ba; B is one of Mn, Co, Ni; and x is larger than 0 but smaller than 1.

According to an embodiment of the first aspect said material has the chemical formula Gd₍₁₋ₓ₎CaₓMnO₃, where x is larger than 0 but smaller than 1.

According to an embodiment of the first aspect said x is in one of the following ranges: 0.31-0.99, 0.35-0.99, 0.4-0.98, 0.45-0.97, 0.5-0.96, 0.55-0.95, 0.6-0.95, 0.65-0.95, 0.7-0.95, 0.75-0.95, 0.8-0.95, 0.85-0.95.

According to a second aspect there is provided use of a material of the kind described above to construct a memristor.

According to a third aspect there is provided a memristor comprising a piece of memristor material that constitutes at least one memristive connection between first and second contacts, wherein the memristor material is a material of the kind described above.

According to an embodiment of the third aspect the piece of memristor material constitutes a film on top of a substrate, wherein a thickness of the film in a direction perpendicular to a surface of said substrate is between 1 nanometre and 500 nanometres.

According to an embodiment of the third aspect said thickness of the film is between 10 and 100 nanometres.

According to an embodiment of the third aspect said first contact consists predominantly of a first material and said second contact consists predominantly of a second material different from said first material.

According to an embodiment of the third aspect the rectifying properties of the junction between the first material and the memristive material are different from the rectifying properties of the junction between the second material and the memristive material.

According to an embodiment of the third aspect the first material is one of: aluminium, titanium.

According to an embodiment of the third aspect the second material is one of: gold, silver, copper, platinum, palladium, indium, SrRuO₃.

According to an embodiment of the third aspect said substrate consists predominantly of one of: strontium titanate SrTiO₃, silicon, lanthanum aluminate—strontium aluminium tantalite (LaAlO₃)_{0.3}(Sr₂TaAlO₆)_{0.7} (LSAT), lanthanum aluminate LaAlO₃ (LAO).

According to a fourth aspect there is provided a microelectronic circuit comprising at least one memristor of the kind described above.

According to a fifth aspect there is provided a method for manufacturing a memristor of a memristor material. The method comprises using Gd₍₁₋ₓ₎CaₓMnO₃ as the memristor material, where x is larger than 0 but smaller than 1.

According to an embodiment of the fifth aspect the method comprises depositing a thin film of said memristor material on top of a substrate.

According to an embodiment of the fifth aspect the method comprises using, for said depositing, at least one of: pulsed laser deposition, other physical vapor deposition, sputtering, chemical vapor deposition, printing.

According to an embodiment of the fifth aspect the method comprises
producing a dry mixture by mixing a first amount of an oxide of gadolinium, a second amount of calcium carbonate, and a third amount of an oxide of manganese,
pelletizing and calcinating said dry mixture,
grinding, repelletizing, and sintering into a solid target, and
using pulsed laser deposition for said depositing, and using said solid target as a target onto which a pulsed laser is focused in said pulsed laser deposition.

According to an embodiment of the fifth aspect the method comprises using a XeCl-laser of wavelength 308 nanometres with energy density of essentially 2 J/cm² and frequency of 5 Hz in said pulsed laser deposition.

According to an embodiment of the fifth aspect the deposition temperature is 700° C. and an oxygen partial pressure is essentially 23 Pa in said pulsed laser deposition.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. In the drawings:

FIG. 1 illustrates a memristor represented by a drawing symbol,

FIG. 2 illustrates a dependence between voltage and current in high and low resistivity states of a memristor,

FIG. 3 illustrates a memristor of a planar type,

FIG. 4 illustrates a memristor of a transversal type,

FIG. 5 illustrates a memristor of a multi-layer type,

FIG. 6 illustrates a pulse train that can be used to characterize a memristor,

FIG. 7 illustrates an idealized resistance of a memristor as a function of the voltage used to set the memristor into a particular resistance state,

FIG. 8 illustrates an example of a measured resistance of a memristor as a function of the voltage used to set the memristor into a particular resistance state,

FIG. 9 illustrates a measured resistance of a memristor made of a first material,

FIG. 10 illustrates a measured resistance of a memristor made of a second material,

FIG. 11 illustrates a measured resistance of a memristor made of a third material,

FIG. 12 illustrates a measured resistance of a memristor made of a fourth material,

FIG. 13 illustrates a measured resistance of a memristor made of a fifth material,

FIG. 14 illustrates a measured resistance of a memristor made of a sixth material,

FIG. 15 illustrates a measured resistance of a memristor made of a seventh material,

FIG. 16 illustrates a measured resistance of a memristor made of an eighth material,

FIG. 17 illustrates a measured resistance of a memristor made of a ninth material,

FIG. 18 illustrates a measured resistance of a memristor made of a tenth material,

FIG. 19 illustrates a measured resistance of a memristor made of an eleventh material,

FIG. 20 illustrates a measured resistance of a memristor made of a twelfth material,

FIG. 21 illustrates measured switching ratios of memristors made of different materials,

FIG. 22 illustrates a measured current through a memristor with contacts made of a different materials,

FIG. 23 illustrates a manufacturing method,

FIG. 24 illustrates a detailed step of the method of FIG. 23,

FIG. 25 illustrates a pulse train that can be used to characterize a linear response of a memristor,

FIG. 26 illustrates another pulse train that can be used to characterize a linear response of a memristor,

FIG. 27 illustrates measured results of a transformation with different write pulse lengths and amplitudes.

### DETAILED DESCRIPTION

FIG. 3 is a schematic cross section of a memristor, which here is of the so-called planar type. The memristor comprises a piece of memristor material 301 that constitutes a memristive connection between a first contact 302 and a second contact 303. The expression “memristor material” is used here for the purpose of unambiguously referring to the material that appears between the contacts, although it is the current understanding that the memristor-type effects actually arise in the junction or interface between the memristor material and the contact, not in the bulk of the memristor material itself. Electrically conductive connections couple the first and second contacts 302 and 303 to respective nodes 304 and 305, which can be used to subject the piece of memristor material 301 to desired voltages and to measure the resulting electric characteristics of the piece of memristor material 301.

The piece of memristor material 301 constitutes a film on top of a substrate 306. In a memristor of the planar type, like the one shown in FIG. 3, the piece of memristor material 301 can be deposited in the form of a film directly on the surface of the substrate 306, but this is not a requirement; intermediate layers of desired materials can be used there-between if they are advantageous for example for achieving better compatibility between crystal structures of the various materials involved.

FIG. 4 is a schematic cross section of a memristor, which here is of the so-called transversal type, sometimes also referred to as the capacitor type. Also in this case the piece of memristor material 301 constitutes a memristive connection between a first contact 302 and a second contact 303, and electrically conductive connections couple these to respective nodes 304 and 305. The piece of memristive material 301 constitutes a film that is on top of the substrate 306, but not directly on top thereof because the second contact 303 constitutes a layer there-between. A memristor of the transversal type like the one shown here has certain advantageous features in comparison with the planar type of FIG. 3: for example, it may require lower operating voltages. However, its manufacturing also requires more steps than the manufacturing of a memristor of a planar type.

FIG. 5 is a schematic cross section of a memristor of the multilayer type. In this case there are two or more pieces of memristor material 301, each of which may be sandwiched between other layers. In the exemplary structure shown in FIG. 5 the intermediate layers are layers of the first and second contacts 302 and 303, so that each piece of memristor material 301 has a first contact layer on its one side and a second contact layer on its other side in the transversal direction, i.e. the direction perpendicular to the surface of the substrate 306.

In all these and other example embodiments where the piece of memristive material constitutes a film on top of a substrate, a thickness d of the film in a direction perpendicular to the surface of the substrate may be for example between 1 and 500 nanometres, or in one preferred embodiment between 10 and 100 nanometres. The thickness d of the film does not need to be constant across its whole area, but in many deposition methods that can be used to produce thin films of this kind a constant thickness of the film is a relatively common default feature of the method.

The first and second contacts 302 and 303 may be made of the same material, or they be made of different materials. Saying that a contact is made of a particular material is synonymous to saying that the respective contact consists predominantly of that material, to the extent that the characteristics of that material dominate the effects that are observed at the interface between the contact and the piece of memristive material. In a number of embodiments that have been found to exhibit interesting characteristics the first and second materials are different materials. In particular, it has been found that the memristor may exhibit certain interesting characteristics if the rectifying properties of the junction between the first material and the memristive material are different from the rectifying properties of the junction between the second material and the memristive material.

An example of a material that can be used as the first material is aluminium. Other examples of materials that can be used as the first material exist as well, and include but are not limited to titanium.

Examples of materials that can be used as the second material are gold and silver. Other examples of materials that can be used as the second material exist as well, and include but are not limited to copper, platinum, palladium, indium, and SrRuO₃.

The typical property of a memristor is that its current-conducting properties depend on electric conditions it has been previously subjected to. In this description of particular interest are memristors that can be “programmed” to have a certain resistance value by applying a “write” pulse of a certain amplitude. Even more interesting are memristors that have a linear or log-linear response to write pulses of different amplitudes. This concept is described in more detail in the following.

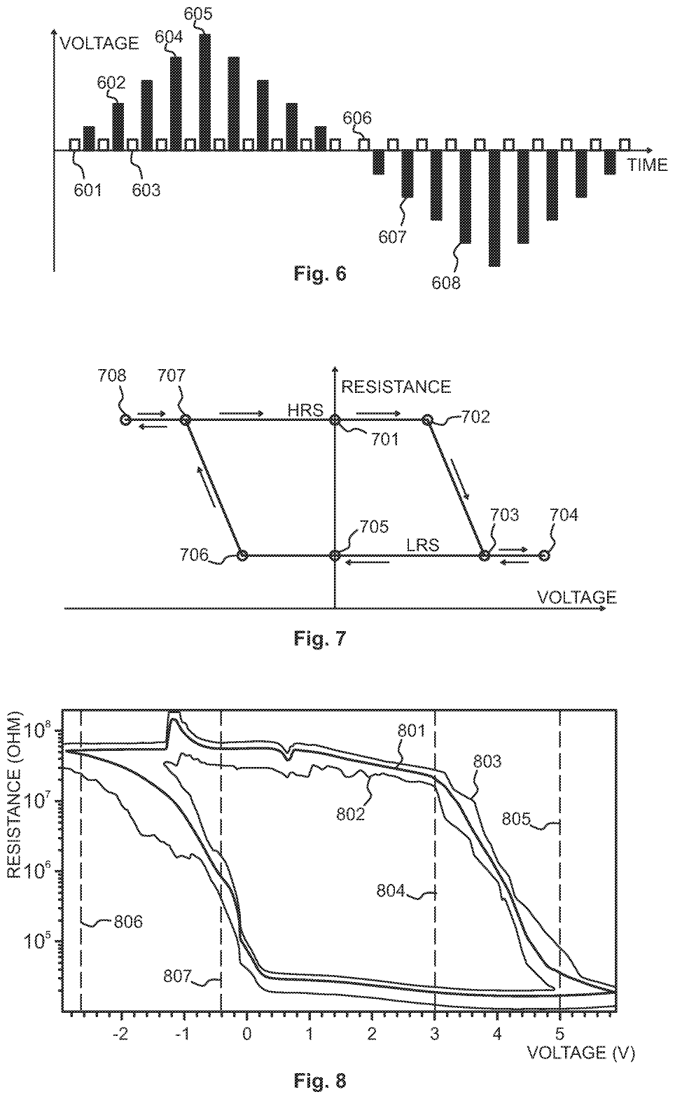

FIG. 6 illustrates a train of voltage pulses, in which the low pulses marked with white are so-called read pulses and the higher pulses marked with black are so-called write pulses. FIG. 7 illustrates how the resistance of a memristor could ideally behave when subjected to a pulse train like that in FIG. 6. The voltage axis in FIG. 7 corresponds to the amplitude of the last write pulse that the memristor has been subjected to. Each read pulse gives a point on the loop-formed graph of FIG. 7. As such, the resistance of the memristor can be read both during a currently ongoing write pulse and during the subsequent read pulse; in ideal case these readings should give the same resistance value. In reality the pulse train may comprise a very much larger number of write pulses at a very much finer resolution, but the illustration in FIG. 6 gives a good conceptual view of how characterizing the memristor may proceed.

Assuming that the memristor is initially in its high resistance state HRS, the first read pulse gives the point 701 in FIG. 7. A number of write pulses of increasing amplitude may pass without a change in the resistance of the memristor, because there may be a first threshold write voltage that is required to cause any change in its current-conducting properties. Here it is assumed that the second write pulse 602 is just at the limit of the first threshold write voltage, so the subsequent read pulse 603 still gives the HRS resistance value at point 702.

The region of linear or log-linear response begins from point 702 so that each write pulse of increasing amplitude after that makes the memristor assume an unambiguously corresponding, increasingly lower resistance. Due to the coarse resolution of the schematic pulse train in FIG. 6 there are not many such pulses shown, but as explained earlier the actual resolution that can be achieved in a real measurement may be much better.

At some point a second threshold write voltage is reached, after which the memristor does not assume any lower resistance even if the amplitude of the write pulses would be increased further. In FIG. 6 the write pulse marked as 604 is shown as reaching the second threshold write voltage, corresponding to point 703 in FIG. 7. The next write pulse 605 has an even larger amplitude, but the resistance of the memristor does not change any more, as shown by point 704 in FIG. 7.

After the largest-amplitude positive write pulse 605 the amplitude of the write pulses in FIG. 6 begins to decrease towards zero. In the graph of FIG. 7 it is assumed that write pulses of increasingly lower amplitude do not change the resistance of the memristor, so that the read pulse 606 that follows the write interval where actually no write pulse occurs gives point 705 in the graph of FIG. 7.

In the ideal case of FIG. 7 the behavior of the memristor in response to write pulses of negative polarity is similar to that with write pulses of positive polarity, although e.g. the selection of the contact materials may cause significant differences in factors such as the absolute magnitude of the threshold voltages. In the idealized example of FIGS. 6 and 7 the first few write pulses of negative polarity still make no change to the LRS resistance of the memristor, until there comes a write pulse 607 the amplitude of which just meets a third threshold write voltage at point 706. A region of linear or log-linear response follows, until the amplitude of a yet further write pulse 608 reaches a fourth threshold write voltage at point 707. Even if write pulses of increasingly larger negative amplitude would follow, the resistance of the memristor would not increase further but would remain constant on the HRS level, as shown by point 708 in FIG. 7. The remaining write pulses in the sequence shown in FIG. 6 have smaller and smaller negative amplitudes, corresponding returning towards the initial point 701 on the upper horizontal section of the loop-formed graph in FIG. 7.

Subjecting a real memristor to a pulse train resembling that of FIG. 6 and repeatedly reading its resistance seldom gives a graph as idealized as in FIG. 7. However, sufficiently close resemblance has been found with memristors in which the memristor material has the chemical formula Gd₍₁₋ₓ₎CaₓMnO₃, where x is larger than 0 but smaller than 1. FIG. 8 illustrates an example of one such real-life measurement. The memristor in question was subjected to repeated measurement rounds, in which a pulse train resembling that of FIG. 6 was repeated a large number of times. The thick graph 801 in FIG. 8 illustrates an arithmetic mean of all loop-formed graphs that resulted in the performed measurements, while the thin graphs 802 and 803 illustrate limits within which the loop-formed graphs of all measurements were contained. The two vertical dashed lines 804 and 805 on the right in FIG. 8 delineate a first region of essentially linear or log-linear response, and the other two vertical dashed lines 806 and 807 delineate a second region of essentially linear or log-linear response.

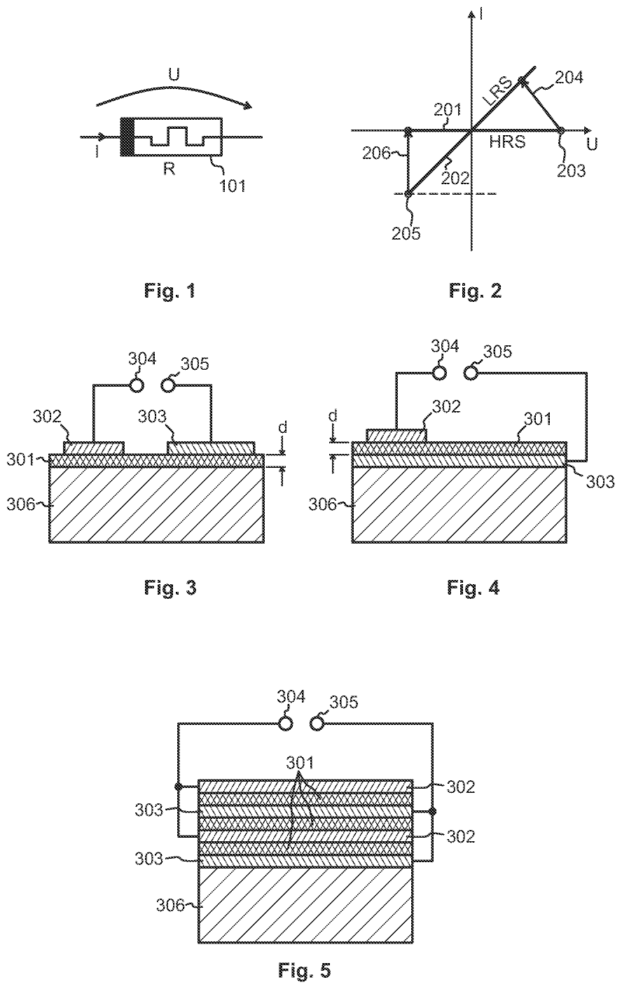

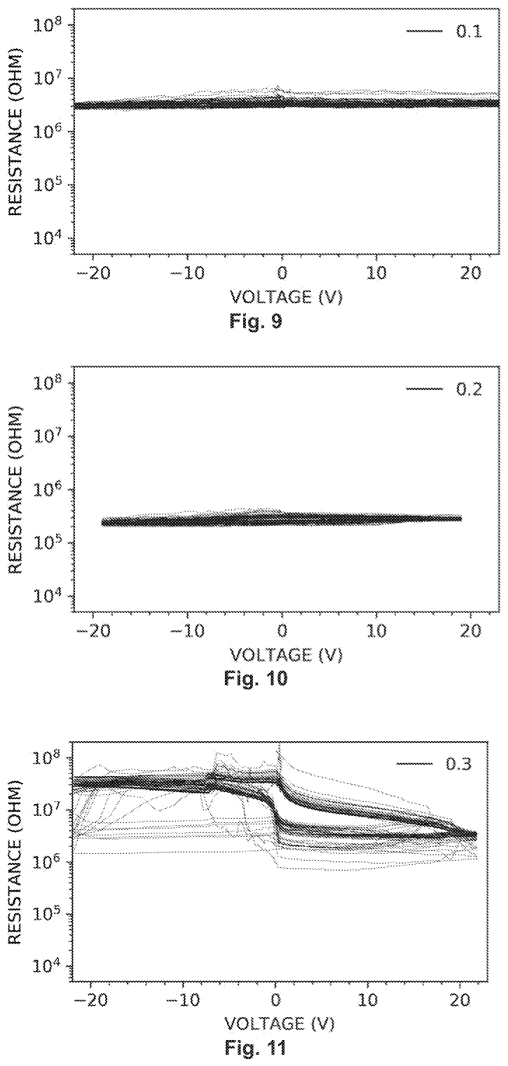

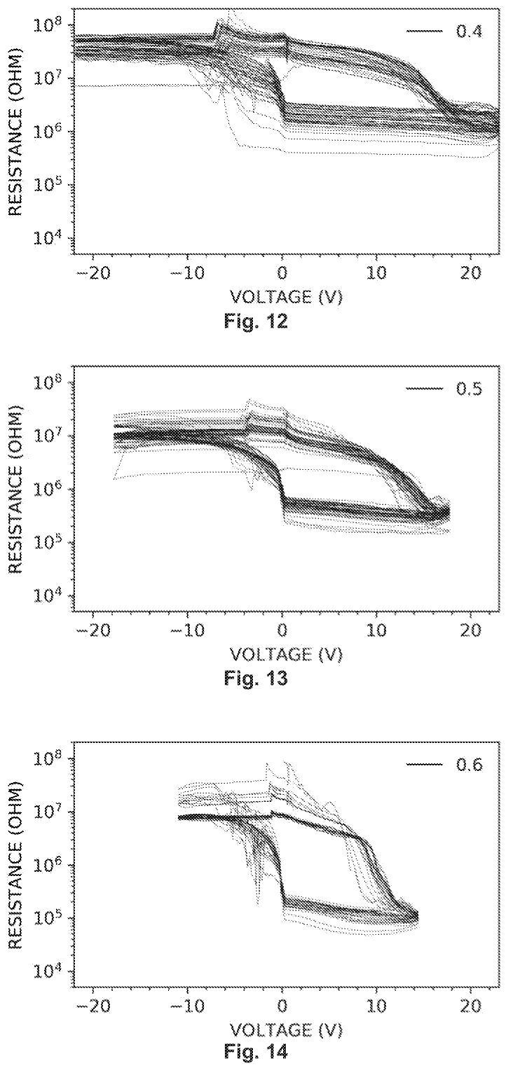

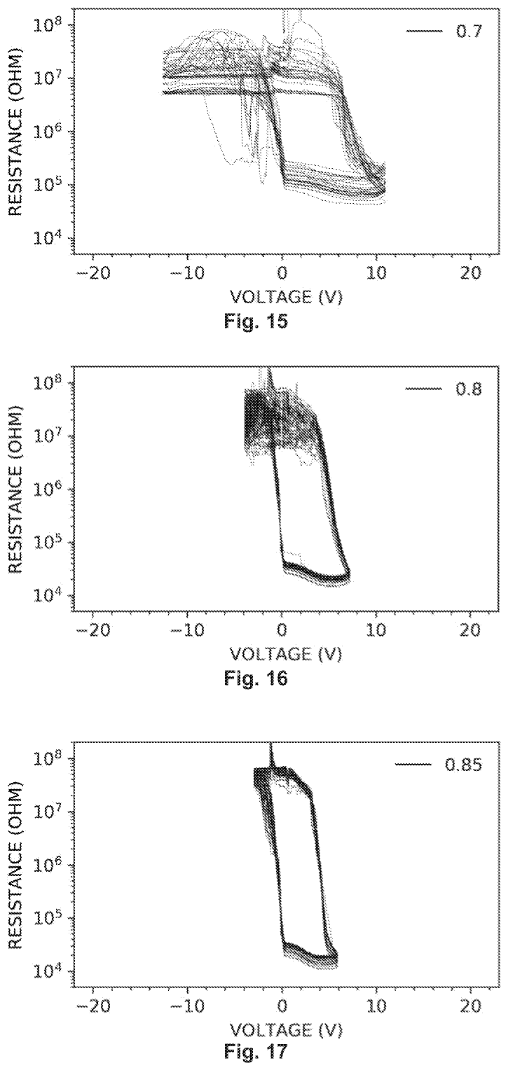

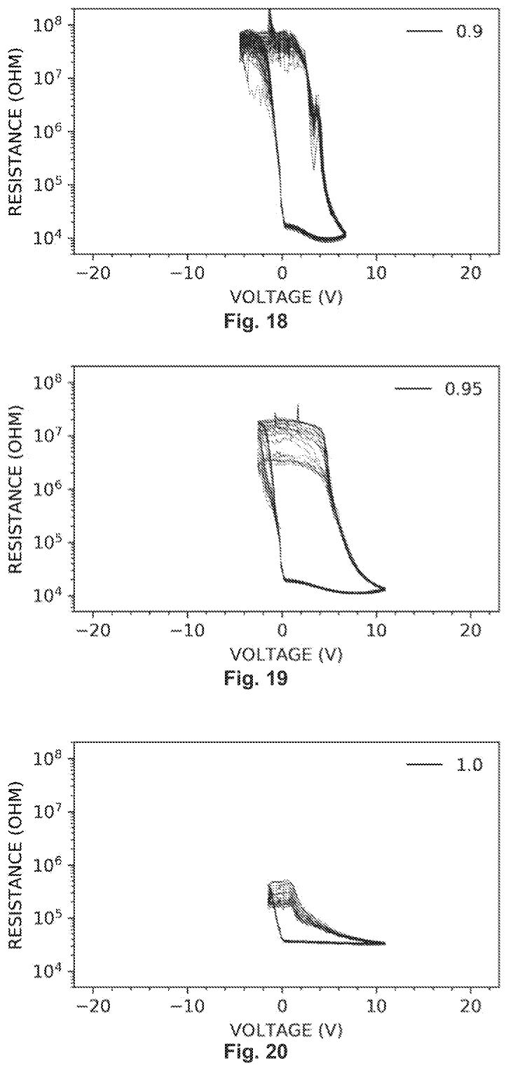

FIGS. 9-20 illustrate further results from measurements like that described above, the difference being in the value of the variable x in the compound Gd₍₁₋ₓ₎CaₓMnO₃ that was used as the memristive material. The values of x are 0.1 in FIG. 9, 0.2 in FIG. 10, 0.3 in FIG. 11, 0.4 in FIG. 12, 0.5 in FIG. 13, 0.6 in FIG. 14, 0.7 in FIG. 15, 0.8 in FIG. 16, 0.85 in FIG. 17, 0.9 in FIG. 18, 0.95 in FIGS. 19, and 1.0 in FIG. 20. In each of FIGS. 9-20 the horizontal axis shows the voltage of the write pulses in volts, and the vertical axis shows the measured resistance of the memristor in ohms. It can be seen that the value of x has a pronounced effect on the characteristic behavior of the memristor. Most advantageous response of the memristor to the applied write pulses was found with values of x larger than 0.3. Classes of embodiments with different levels of advantageousness were found when x was in one of the following ranges: 0.31-0.99, 0.35-0.99, 0.4-0.98, 0.45-0.97, 0.5-0.96, 0.55-0.95, 0.6-0.95, 0.65-0.95, 0.7-0.95, 0.75-0.95, 0.8-0.95, 0.85-0.95.

Another characteristic that can be seen in at least some of FIGS. 9-20 is a so-called cumulative effect of write pulses even after the write pulse of largest amplitude has passed already. For example in the lower right part of the loop-formed graphs of FIG. 19 it can be seen that once the voltage values begin to decrease from the maximum of about 11 V, the graphs do not continue directly horizontally to the left but make a bend towards even somewhat smaller resistance values between decreasing amplitude values of the most recent write pulse from said about 11 V to about 2 V. This cumulative effect of the write pulses may be advantageous in some applications in which there is value in the capability of tracking the occurrence of smaller amplitude pulses after larger amplitude ones.

In addition to the linear or log-linear response of the memristor to the amplitude of applied write pulses, another quantity of interest is the switching ratio, defined as a ratio Rmax/Rmin. Here Rmax means the HRS resistance and Rmin means the LRS resistance of the memristor that can be observed with a read pulse after a complete loop of write pulses have been applied. In the idealized case of FIG. 7 the value Rmax would be the resistance reading at point 701, and the value Rmin would be the resistance reading at point 705. The larger the switching ratio, the easier it may be to utilize the memristor in practical applications like neuromorphic computing, because the required resolution in a quantity like e.g. the connection strength between nodes of a neural network does not need to be that fine.

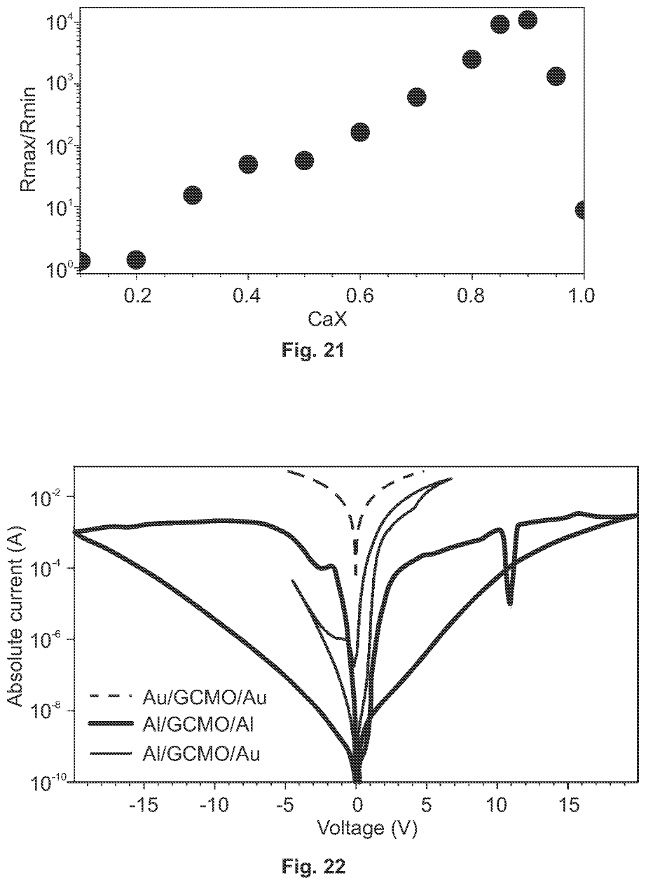

FIG. 21 illustrates the switching ratios that were obtained by producing memristors of the memristor material mentioned above with x=0.1, x=0.2, x=0.3, x=0.4, x=0.5, x=0.6, x=0.7, x=0.8, x=0.85, x=0.9, x=0.95, and x=1 (the black dots from left to right in FIG. 21). These measurements suggest that with values of x less than 0.2 it may be difficult to obtain a switching ratio sufficient for many practical applications known at the time of writing this description, while with values of x increasing towards 0.9 increasingly larger switching ratios can be obtained with values such as even four orders of magnitude or more being possible to achieve.

Possible materials for the contacts were discussed briefly earlier in this text. FIG. 22 illustrates a comparison of measured current values through the memristor with both contacts made of gold (dashed line), both contacts made of aluminium (thick solid line) and one contact made of aluminium and one of gold (thin solid line). The rectifying properties of the junction between aluminium and the memristive material are different from the rectifying properties of the junction between gold and the memristive material, which appears to cause the large differences in the measurements shown in FIG. 22.

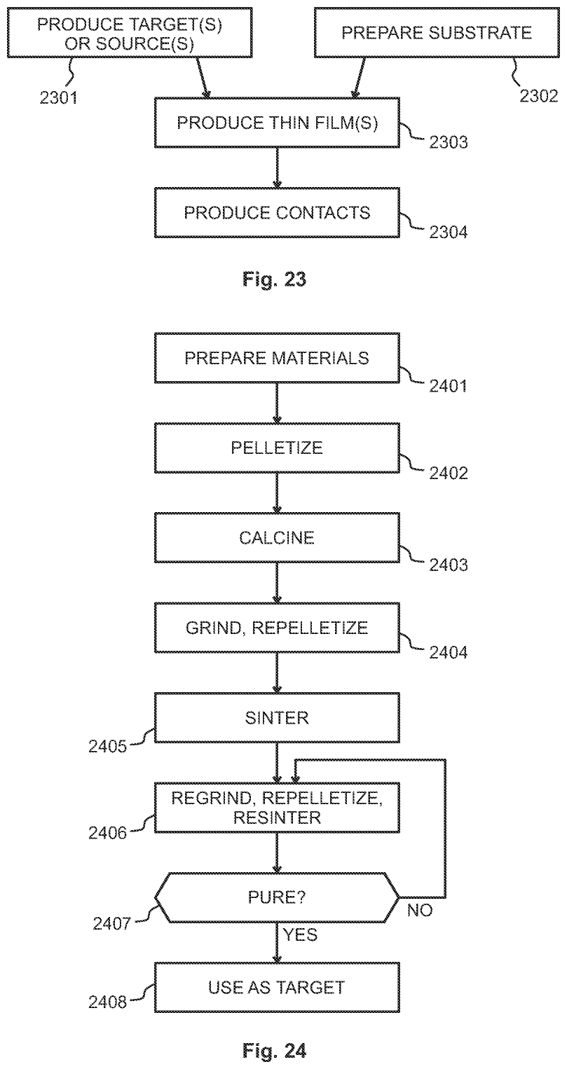

FIG. 23 illustrates a method for manufacturing a memristor of a memristor material of a kind described above. Here it is assumed that in the method the memristive material will be deposited on top of a substrate, but other ways of manufacturing the memristor are not excluded either. Step 2301 represents one or more preparatory steps that aim at providing the memristor material in the form of a target or source that can be used in a thin film depositing technique such as pulsed laser deposition, molecular beam epitaxy, electron beam evaporation, or the like. Also other targets or sources may be produced at step 2301, for example if the memristor structure is to comprise auxiliary layers such as contacts, insulators, and/or the like. Step 2302 represents one or more preparatory steps that aim at providing a substrate on top of which the memristor material can be deposited. Step 2303 represents producing one or more thin films on top of the substrate so that at least one of such thin films comprises the memristor material. The production of contacts to the memristor material is shown as a separate step 2304 in FIG. 23. As an example, if pulsed laser deposition is used as the method of depositing the memristor material, DC magnetron sputtering with shadow mask(s) can be used to deposit the layers of the first and possibly second contact material that are to constitute the contacts to the memristive material.

FIG. 24 illustrates an example of how the preparation of a target in step 2301 of FIG. 23 may look like. In the example embodiment of FIG. 24 the first step 2401 represents initially preparing component materials such as gadolinium(III) oxide, calcium carbonate, and manganese(IV) oxide in suitable amounts for example by drying them overnight in hot (like 200° C.) air and mixing the dried component materials in a mortar. The relative amounts of the component material containing gadolinium and the component material containing calcium will eventually define the value of x in the completed target material Gd₍₁₋ₓ₎CaₓMnO₃. Step 2402 represents pelletizing the mixture of component materials, and step 2403 represents calcination of the pelletized mixture for example by using a 7.5 hours-60 hours pass of temperature 25° C.→750° C.→25° C. in air. Step 2404 represents grinding the outcome of step 2403 in a mortar and repelletizing. Step 2405 represents sintering for example by using a 13 hours-24 hours pass of temperature 25° C.→1300° C.→25° C. in air. Step 2406 represents grinding the outcome of step 2405 in a mortar, repelletizing, and resintering into a solid target or source. Step 2407 represents using

X-ray diffraction to measure the outcome of step 2406 and performing Rietveld refinement. If the material is not found to be pure enough, a return to step 2406 occurs. A solid target or source that is found to exhibit sufficient purity in step 2407 may be used as a target or source in a thin film deposition process according to step 2408, for example using said solid target as a target onto which the pulsed laser is focused in pulsed laser deposition. As an example, a XeCl-laser of wavelength 308 nanometres with energy density of essentially 2 J/cm2 and frequency of 5 Hz can be used in said pulsed laser deposition. Examples of process parameter values in such pulsed laser deposition are a deposition temperature of 700° C. and an oxygen partial pressure of essentially 23 Pa. The values of laser energy density, laser pulse frequency, deposition temperature, and oxygen partial pressure given here are just examples, and many other combinations of many other values of these parameters could be utilized.

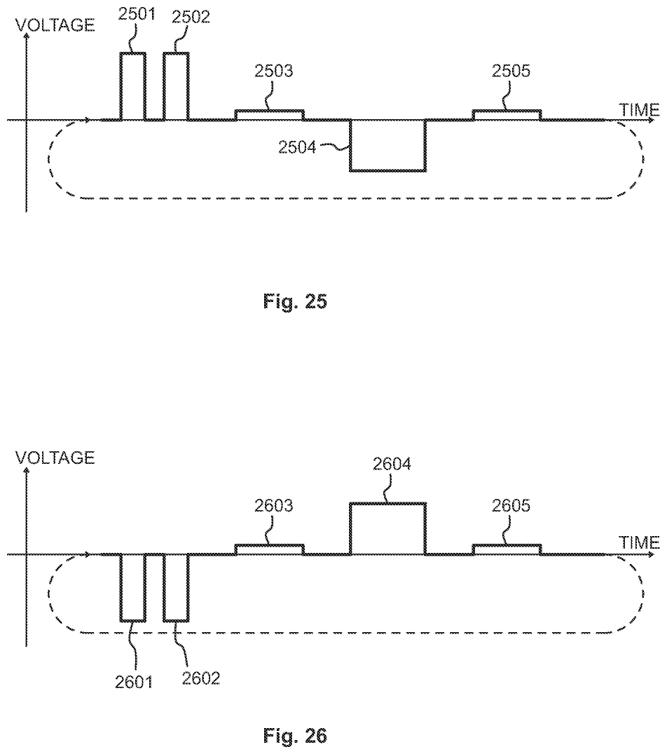

FIGS. 25 and 26 illustrate examples of pulse trains that can be used to characterize a linear response of a memristor of the kind described above. In FIG. 25 the linear response in an LRS→HRS transition can be examined. The pulse train begins with two so-called reset pulses 2501 and 2502, the polarity of which is chosen so that they convincingly set the memristor in the low resistivity state LRS. The amplitude of the reset pulses 2501 and 2502 may be for example in the order of +7 V, assuming that the memristor is of the planar type, that the value x in the memristor material is between 0.7 and 0.95, and that one of the contacts is made of gold and the other of aluminium. The length of each of the reset pulses 2501 and 2502 may be for example in the order of 0.45 ms, but also significantly shorter or longer reset pulses are possible: a useful length of a reset pulse may be between 100 ns and 2 ms, or even shorter, like 100 ps. A pause of the order of 5 ms may be had between the reset pulses 2501 and 2502.

A first read pulse 2503 may be applied in order to check through measurement that the memristor is truly in the LRS. The amplitude of the read pulse 2503 may be for example in the order of +0.45 V; in any case it should be selected low enough to ensure that the read pulse does not cause any significant change in the LRS of the memristor. The time interval between the later reset pulse 2502 and the read pulse 2503 may be for example in the order of 0.5 s, or between 0.1 s and 1 s, and the duration of the read pulse 2503 may be for example in the order of 0.5 s. What is described here as a single read pulse may in practice be a series of read pulses, like 20 read pulses, so that the average read value of the LRS resistance is calculated from the readings given by individual pulses.

A write pulse 2504 may be applied in order to make the memristor undergo a transition from the LRS to a higher resistance state. For the purposes of characterizing linear response, and assuming the structural and material-related factors of the memristor named above, the amplitude of the write pulse 2504 may be varied between for example −1 V and −6.5 V. The length of the write pulse 2504 may be varied for example between 50 and 250 ms, but also significantly shorter write pulses can be applied, for example in the order of 100 ns. After the write pulse 2504 a further pause of for example 1 s may be had, and a further read pulse 2505 may be applied to read the transformed resistance of the memristor. Again, what is described here as a single read pulse may in practice be a series of read pulses, like 20 read pulses, so that the average read value of the transformed resistance is calculated from the readings given by individual pulses. Thereafter a return to the beginning of the pulse train may occur, and another pulse train, possibly with some other amplitude and/or duration of the write pulse 2504, may be applied.

In FIG. 26 the linear response in an HRS→LRS transition can be examined. The pulse train begins again with two so-called reset pulses 2601 and 2602, the polarity of which is this time chosen so that they convincingly set the memristor in the high resistivity state HRS. The amplitude of the reset pulses 2601 and 2602 may be for example in the order of −7.6 V, assuming that the memristor is of the planar type, that the value x in the memristor material is between 0.7 and 0.95, and that one of the contacts is made of gold and the other of aluminium. The length of each of the reset pulses 2601 and 2602 may be for example in the order of 1.4 ms, or between 0.1 ms and 2 ms. A pause of the order of 5 ms may be had between the reset pulses 2601 and 2602.

A first read pulse 2603 may be applied in order to check through measurement that the memristor is truly in the HRS. The amplitude and other characteristics of the read pulse 2603 (or sequence of first read pulses) may be similar to those of the first read pulse (or sequence of first read pulses) in FIG. 25.

A write pulse 2604 may be applied in order to make the memristor undergo a transition from the HRS to a lower resistance state. For the purposes of characterizing linear response, and assuming the structural and material-related factors of the memristor named above, the amplitude of the write pulse 2604 may be varied between for example +3.5 V and +5.5 V and the length of the write pulse 2604 may be varied for example between 20 and 120 ms. After the write pulse 2604 a further pause of for example 0.5 s may be had, and a further read pulse 2605 may be applied to read the transformed resistance of the memristor. Again, what is described here as a single read pulse may in practice be a series of read pulses, like 20 read pulses, so that the average read value of the transformed resistance is calculated from the readings given by individual pulses. Thereafter a return to the beginning of the pulse train may occur, and another pulse train, possibly with some other amplitude and/or duration of the write pulse 2604, may be applied.

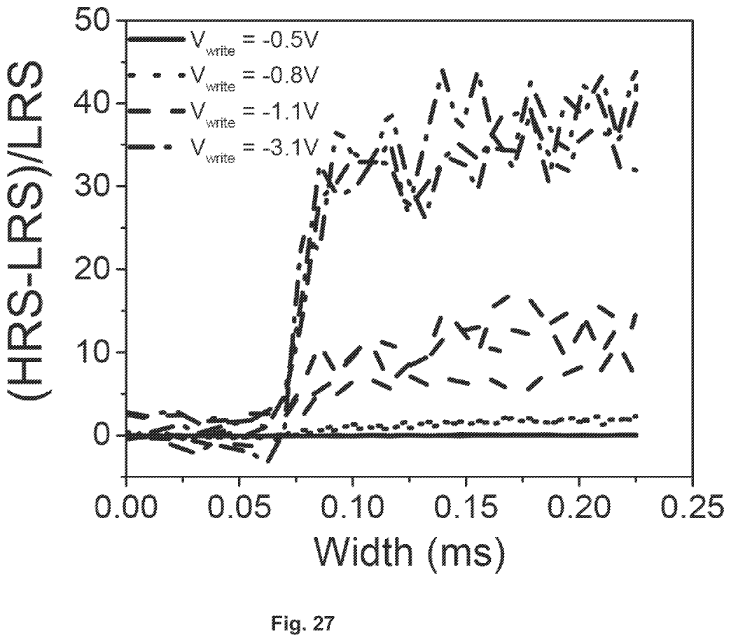

FIG. 27 shows measured results of the ratio (HRS-LRS)/LRS, with different amplitudes and durations of write pulses. Each individual graph in FIG. 27 represents a write pulse amplitude according to the associated legend, and the horizontal axis represents the width of the respective write pulse in milliseconds. These measurements show that both the amplitude and the duration in time of the write pulse have significance in making the memristor undergo a resistance transformation, and that linear or log-linear behavior over a relatively wide range of transformed resistances can be achieved.

It is obvious to a person skilled in the art that with the advancement of technology, the basic idea of the invention may be implemented in various ways. As an example, in place of or in addition to pulsed laser deposition also other forms of thin film deposition methods can be used, such as other physical vapor deposition methods, sputtering, chemical vapor deposition, or printing. Also, even if gadolinium has been mostly described as the element that was marked as R in the general chemical formula, other elements such as europium, terbium, or neodymium could be used. Similarly even if calcium has been mostly described as the element that was marked as A, other elements such as strontium, or barium could be used. Similarly even if manganese has been mostly describes as the element that was marked as B, other elements such as cobalt or nickel could be used. The invention and its embodiments are thus not limited to the examples described above, instead they may vary within the scope of the claims.

1.-21. (canceled)

22. A material for memristor, which material has the chemical formula R₍₁₋ₓ₎AₓBO₃, where R is one of Eu, Gd, Tb, Nd; A is one of Ca, Sr, Ba; B is one of Mn, Co, Ni; and x is larger than 0 but smaller than 1.

23. A material according to claim 22, wherein the chemical formula of the material is Gd₍₁₋ₓ₎CaₓMnO₃, where x is larger than 0 but smaller than 1.

24. A material according to claim 22, wherein x is in one of the following ranges: 0.31-0.99, 0.35-0.99, 0.4-0.98, 0.45-0.97, 0.5-0.96, 0.55-0.95, 0.6-0.95, 0.65-0.95, 0.7-0.95, 0.75-0.95, 0.8-0.95, 0.85-0.95.

25. Use of a material that has the chemical formula R₍₁₋ₓ₎AₓBO₃, where R is one of Eu, Gd, Tb, Nd; A is one of Ca, Sr, Ba; B is one of Mn, Co, Ni; and x is larger than 0 but smaller than 1, to construct a memristor.

26. A memristor comprising a piece of memristor material that constitutes at least one memristive connection between first and second contacts, wherein the memristor material has the chemical formula R₍₁₋ₓ₎AₓBO₃, where R is one of Eu, Gd, Tb, Nd; A is one of Ca, Sr, Ba; B is one of Mn, Co, Ni; and x is larger than 0 but smaller than 1.

27. A memristor according to claim 26, wherein the piece of memristor material constitutes a film on top of a substrate, wherein a thickness of the film in a direction perpendicular to a surface of said substrate is between 1 nanometres and 500 nanometres.

28. A memristor according to claim 27, wherein said thickness of the film is between 10 and 100 nanometres.

29. A memristor according to claim 26, wherein said first contact consists predominantly of a first material and said second contact consists predominantly of a second material different from said first material.

30. A memristor according to claim 29, wherein the rectifying properties of the junction between the first material and the memristive material are different from the rectifying properties of the junction between the second material and the memristive material.

31. A memristor according to claim 30, wherein the first material is one of: aluminium, titanium.

32. A memristor according to claim 30, wherein the second material is one of: gold, silver, copper, platinum, palladium, indium, SrRuO₃.

33. A memristor according to claim 27, wherein said substrate consists predominantly of one of: strontium titanate SrTiO₃, silicon, lanthanum aluminate—strontium aluminium tantalite (LaAlO₃)_{0.3}(Sr₂TaAlO₆)_{0.7} (LSAT), lanthanum aluminate LaAlO₃ (LAO).

34. A microelectronic circuit comprising at least one memristor, wherein said memristor comprises a piece of memristor material that constitutes at least one memristive connection between first and second contacts, wherein the memristor material has the chemical formula R₍₁₋ₓ₎AₓBO₃, where R is one of Eu, Gd, Tb, Nd; A is one of Ca, Sr, Ba; B is one of Mn, Co, Ni; and x is larger than 0 but smaller than 1.

35. A method for manufacturing a memristor of a memristor material, the method comprising using a material with the chemical formula R₍₁₋ₓ₎AₓBO₃ as said memristor material, where R is one of Eu, Gd, Tb, Nd; A is one of Ca, Sr, Ba; B is one of Mn, Co, Ni; and x is larger than 0 but smaller than 1.

36. A method according to claim 35, comprising using Gd₍₁₋ₓ₎CaₓMnO₃ as the memristor material, where x is larger than 0 but smaller than 1.

37. A method according to claim 35, comprising depositing a thin film of said memristor material on top of a substrate.

38. A method according to claim 37, comprising using, for said depositing, at least one of: pulsed laser deposition, other physical vapor deposition, sputtering, chemical vapor deposition, printing.

39. A method according to claim 38, comprising
producing a dry mixture by mixing a first amount of an oxide of R, a second amount of carbonate of A, and a third amount of an oxide of B,
pelletizing and calcinating said dry mixture,
grinding, repelletizing, and sintering into a solid target, and
using pulsed laser deposition for said depositing, and using said solid target as a target onto which a pulsed laser is focused in said pulsed laser deposition.

40. A method according to claim 38, comprising using a XeCl-laser of wavelength 308 nanometres with energy density of essentially 2 J/cm² and frequency of 5 Hz in said pulsed laser deposition.

41. A method according to claim 40, wherein the deposition temperature is 700° C. and an oxygen partial pressure is essentially 23 Pa in said pulsed laser deposition.

42. A method according to claim 35, comprising producing electrically conductive contacts on at least one surface of the memristor material.
